(19) United States
(12) Patent Application Publication
(10) Pub. No.: US 2008/0048262 A1
(43) Pub. Date: Feb. 28, 2008

(54) Fin field effect transistor and method of forming the same

(75) Inventors: Deok-Hyung Lee, Seoul (KR); Sun-Ghil Lee, Yongin-si (KR); Gyeong-Ho Buh, Suwon-si (KR); Jong-Ryeol Yoo, Osan-si (KR); Si-Young Choi, Seongnam-si (KR); Tai-Su Park, Hwaseong-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/892,320

(22) Filed: Aug. 22, 2007

(30) Foreign Application Priority Data
Aug. 22, 2006 (KR) 10-2006-79535

(51) Int. Cl. H01L 27/12; H01L 21/84

(52) U.S. Cl. 257/347; 438/151; 257/E27.111; 257/E21.703

(57) ABSTRACT

Provided are a fin field effect transistor (FinFET) with recess source/drain regions, and a method of forming the same. One example embodiment may provide a semiconductor device including a fin provided on a substrate and extending in a first direction, the fin including a stepped portion, and a gate electrode extending in a second direction crossing the first direction, and provided on a top surface and side surfaces of the stepped portion of the fin.

### PRIORITY CLAIM

A claim of priority is made under 35 U.S.C. § 119 of Korean Patent Application No. 2006-79535, filed on Aug. 22, 2006, the entire contents of which are hereby incorporated by reference.

### BACKGROUND

1. Field

Example embodiments of the present invention may relate to a semiconductor device, and a method of forming the same, and more particularly, to a fin field effect transistor (FinFET) having a step portion, and a method of forming the same.

2. Conventional Art

A semiconductor device may include a field effect transistor having source/drain regions spaced apart from each other on a semiconductor substrate, and a gate electrode formed on a channel region between the source region and the drain region.

As higher degrees of integration are required in semiconductor devices, a size of a transistor needs to be reduced. However, reducing the size of the transistor may cause problems. For example, decreasing a length of a channel deteriorates punch-through effect between the source and drain regions, and deteriorates the controllability of a gate electrode over the channel region, thereby increasing an amount of leakage current. In general, decreasing the size of a planar transistor structure increases the short channel effect; therefore, the planar transistor structure may have reduced transistor characteristics, such as an on-current, off-current, sub-threshold voltage swing, and drain-induced barrier lowering (DIBL). To overcome such limits of the planar transistor structure, transistors with a variety of structures have been developed. A fin field effect transistor (FinFET) with a 3-D structure is regarded as a good substitute for the planar transistor. It has been reported that the FinFET has excellent characteristics for the sub-threshold voltage swing, DIBL, body effect, and on/off current compared to the planar transistor. The FinFET includes a gate electrode that crosses a silicon fin protruding on a substrate. The silicon fin under the gate electrode corresponds to a channel region, and the gate electrode is formed on a top surface and sidewalls of the silicon fin. Thus, the controllability of the gate electrode over the channel region may be improved. Also, source/drain regions are formed in the silicon fin at both sides of the channel region to improve the punch-through effect between the source/drain regions.

FIG. 1 illustrates a conventional FinFET. The conventional FinFET 200 includes a fin 202, and a gate 238 disposed on the fin 202. A gate insulating layer 236 is disposed between the fin 202 and the gate 238. On respective ends of the fin 202 are a drain region 204 and a source region 206. As indicated by the dotted circle of FIG. 1, the conventional FinFET 200 with the 3-D structure has some limitations. For example, in the case of a tri-gate structure, gate-induced drain leakage (GIDL) increases drastically due to an electric field concentration occurring from the gate electrode on the top portion and side surfaces of the fin. The GIDL component also deteriorates static retention characteristic in a dynamic random access memory (DRAM).

### SUMMARY

Example embodiments of the present invention may provide a fin transistor with a new structure, and a method of forming the same.

In an example embodiment of the present invention, a semiconductor device may include a fin provided on a substrate and extending in a first direction, the fin including a stepped portion, and a gate electrode extending in a second direction, crossing the first direction, and provided on a top surface and side surfaces of the stepped portion of the fin.

In another example embodiment, a method of forming a semiconductor device may include forming a fin to extend on a first direction on a substrate, forming a gate electrode to extend on a second direction crossing the first direction on a top surface and sidewalls of the fin, recessing the exposed portions of the fin at both sides of the gate electrode to a desired depth to form a stepped portion, and implanting impurity ions into the recessed fin to form source/drain regions.

### BRIEF DESCRIPTION OF THE FIGURES

The accompanying figures are included to provide a further understanding of example embodiments of the present invention, and are incorporated in and constitute a part of the specification. The drawings and the description may serve to further explain example embodiments of the present invention. In the figures:

FIG. 1 is a cross-sectional view of a fin field effect transistor (FinFET);

FIGS. 2 through 4 schematically illustrate a FinFET according to an example embodiment of the present invention;

FIGS. 5 through 7 are cross-sectional views illustrating a method of forming a FinFET according to an example embodiment of the present invention;

FIGS. 8 through 10 are cross-sectional views illustrating a method of forming a FinFET according to another example embodiment of the present invention;

FIGS. 11 through 12 are cross-sectional views illustrating a method of forming a FinFET according to another example embodiment of the present invention;

FIG. 13 illustrates a result of a simulation of conventional FinFET characteristics;

FIG. 14 illustrates a result of a simulation of a FinFET characteristics according to an example embodiment of the present invention; and

FIG. 15 illustrates Id-Vg curves of the conventional art and an example embodiment of the present invention.

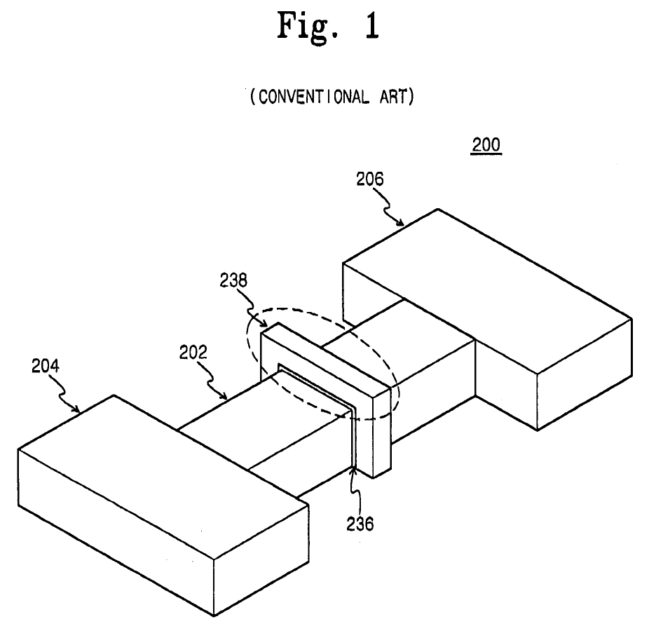

### DETAILED DESCRIPTION

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention in conjunction with the accompanying drawings will be described.

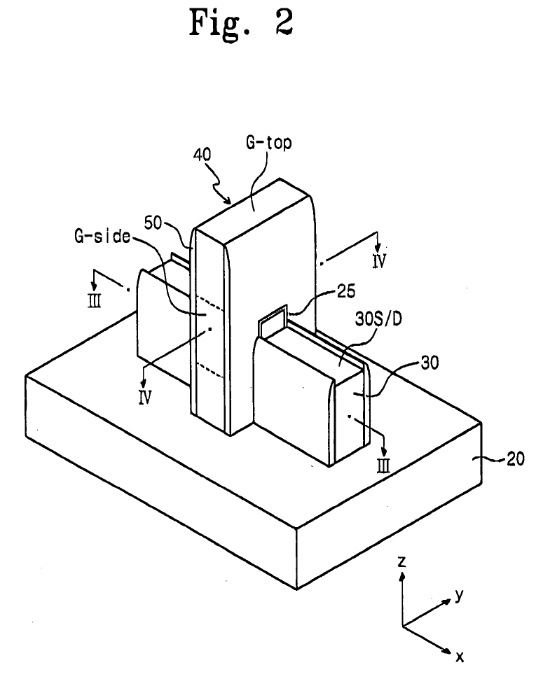

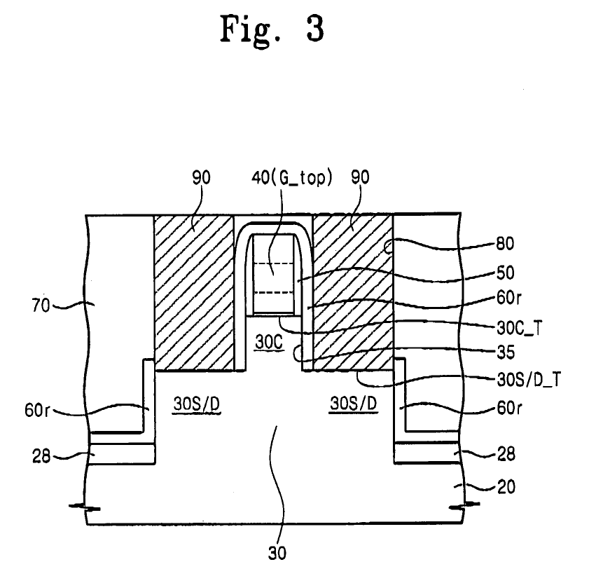

FIG. 2 is a schematic perspective view of a fin field effect transistor (FinFET) according to an example embodiment of the present invention. Referring to FIG. 2, the FinFET may include a fin 30 provided on a substrate 20. The fin 30 may include a top surface and side surfaces. A gate electrode 40 may be formed on the top surface and the side surfaces of the fin 30. A gate insulating layer 25 may be interposed between the gate electrode 40 and the fin 30. Gate spacers 50 may be provided on sidewalls of the gate electrode 40. In FIG. 2, the fin 30 may extend in an x-direction, and the gate electrode 40 may extend in a y-direction. For the convenience of description, a top portion of the gate electrode 40 formed on a top surface of the fin 30 may be called a “top gate electrode G-top,” and a portion of the gate electrode 40 formed on the side surfaces of the fin may be called a “side gate electrode G-side.” Source/drain regions 30S/D may be disposed in the fin 30 at both sides of the gate electrode 40. A fin region on which the gate electrode 40 is formed may be referred to as a “gate fin 30C” (see FIG. 3), and the fin regions in which the source/drain regions 30S/D are formed may be referred to as “source/drain fins.”

According to an example embodiment of the present invention, the fin 30 may be formed by etching the substrate 20 to a desired depth. Also, as can be seen in FIG. 3, which is a cross section (x-direction) view taken along the line III-III of the FinFET of FIG. 2, the gate fin 30C may protrude above the source/drain region 30S/D. That is, the fin 30 including the gate fin 30C may have a stepped shape. The source/drain regions 30S/D may contribute in the decrease of coupling capacitance caused by an overlap between the source/drain regions 30S/D and the gate electrode 40, and may also decrease gate induced drain leakage (GIDL).

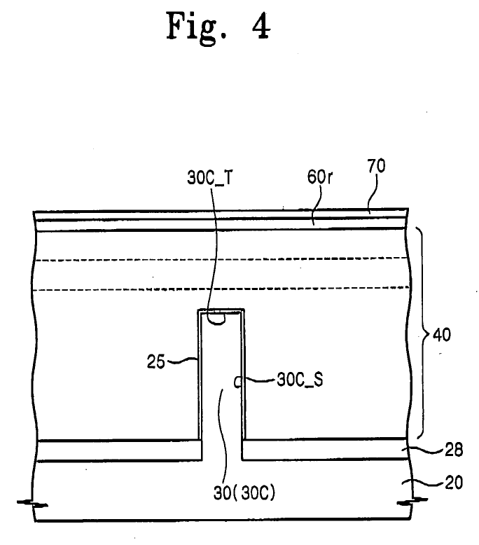

The FinFET structure according to an example embodiment of the present invention will now be described in more detail with reference to FIGS. 3 and 4. FIG. 4 illustrates a vertical section of the FinFET in a y-direction that crosses the fin 30 (i.e., direction corresponding to line IV-IV of FIG. 2). Referring to FIGS. 3 and 4, the gate electrode 40 may be formed to encompass a top surface 30C_T and side surfaces 30C_S of the gate fin 30C. The gate insulating layer 25 may be interposed between the gate electrode 40 and the fin 30. The gate electrode 40 may be formed of polysilicon, tungsten silicide, tungsten nitride, tungsten, silicon nitride, and any combination thereof. The top surface of the gate electrode 40 may be protected by a capping layer (not shown), e.g., a silicon nitride layer. Adjacent fins 30 may be electrically insulated from each other by a divide isolation region 28.

The gate spacers 50 may be provided on both sidewalls of the gate electrode 40. The gate spacer 50 may be formed of, for example, a silicon nitride layer. The source/drain regions 30S/D may be self-aligned with the source/drain fins outside the gate spacer 50. That is, as the fin 30 outside the gate spacers 50 is etched to a desired depth, for example, to about 150 to 500 Å, the recess source/drain regions 30S/D may also be formed

Referring to FIG. 3, since a top surface 30S/D_T of the source/drain region 30S/D may be lower than the top surface 30C_T of the gate fin 30C, the top surface of the fin 30 has a height difference along a direction in which the fin 30 extends (i.e., direction perpendicular to a direction in which the gate electrode 40 extends). Vertical connection portions 35 of the fin 30 may connect lower portions (e.g., source/drain fins) with a higher portion (e.g., gate fin 30C). An etch stopper layer pattern 60r may be provided on the vertical connection portions 35. The etch stopper layer 60r may be further provided on respective sidewalls of the spacers 50. The etch stopper layer pattern 60r may be further provided on the gate electrode 40. The etch stopper layer pattern 60r may serve to prevent impurities from diffusing to the vertical connection portions 35 of the fin 30 during an ion implantation process for forming the source/drain region 30S/D. Since impurity ions may be prevented from being implanted into the vertical connection portions 35 of the fin 30, an electric field created by the top gate electrode G-Top may be lowered, and thus the GIDL may be reduced.

According to an example embodiment of the present invention, an interlayer insulating layer 70 including self-aligned contact holes 80 may be further provided. Self-aligned contact pads 90 contacting the source/drain regions 30S/D may be provided in the self-aligned contact holes 80. The self-aligned contact pads 90 may be formed of, for example, polysilicon or metal. A silicide layer (not shown) may be further provided on the source/drain regions 30S/D to improve contact resistance characteristics with respect to the self-aligned contact pads 90.

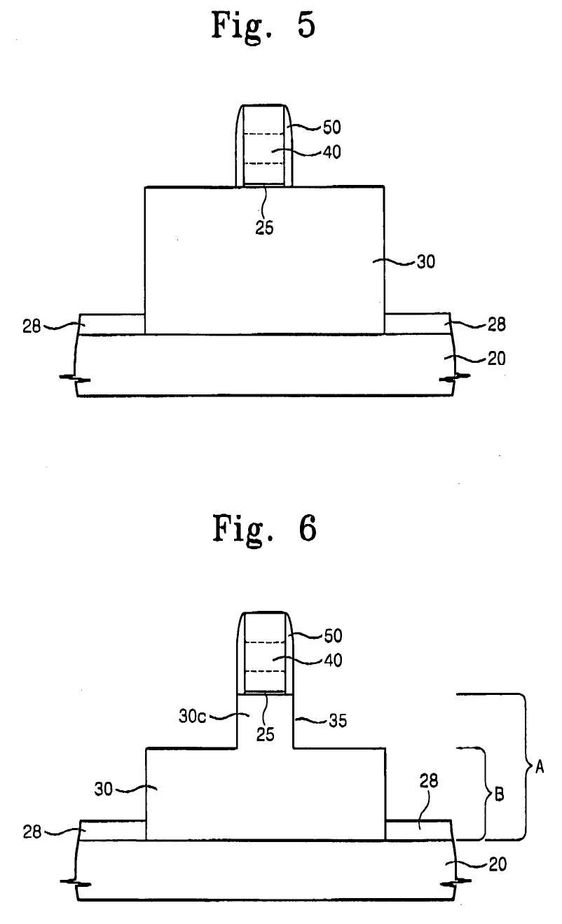

Referring to FIGS. 5 through 7, a method of forming a FinFET according to an example embodiment of the present invention will now be described. FIGS. 5 through 7 illustrate vertical cross-sections in the x-direction that crosses a fin 30 (corresponding to line III-III of FIG. 2). Referring to FIG. 5, a gate insulating layer 25 may be formed on a substrate 20 having a fin 30. Thereafter, a gate electrode 40 of polysilicon, tungsten silicide, tungsten nitride, tungsten, silicon nitride, or any combination thereof may be formed on the gate insulating layer 25. Gate spacers 50 may be formed on sidewalls of the gate electrode 40. The gate spacers 50 may be formed by depositing a silicon nitride (SiN) layer with a thickness ranging from about 100 to 350 Å, and then performing an etch-back process on the resulting structure.

The substrate 20 including the fin 30 may be a bulk substrate or a silicon on insulator (SOI) substrate. When the bulk substrate is used, a fin 30 with a desired height may be formed by etching the bulk substrate to a desired depth. A silicon-geranium substrate, a doped or undoped silicon substrate, or a substrate with an epitaxial layer formed by epitaxial growth may be used as the bulk substrate. After the fin 30 is formed, a device isolation layer 28 may be formed to electrically isolate adjacent fins 30.

Referring to FIG. 6, after the gate spacers 50 are formed, the fin 30 at both sides of the gate spacer 50 may be recessed to a desired depth to thereby form a gate fin 30C. For example, a difference in height in region A, which may include the gate fin 30C, and a height in region B of fin 30, which does not include the gate fin 30C, may be in a range of 150 to 500 Å. To remove any damages caused by the etch process, a thermal oxidation process may be performed.

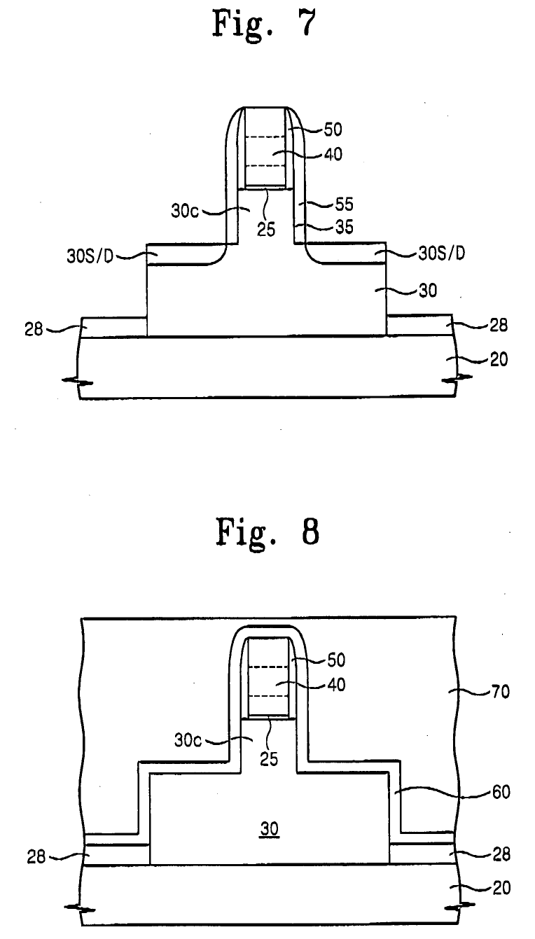

Referring to FIG. 7, impurity ions may be implanted into the fin 30 to form recess source/drain regions 30S/D. Before the impurity ions are implanted, protective spacers 55 may be further formed to protect vertical connection portions 35. The protective spacer 55 may be formed by depositing a silicon nitride layer and then performing an etch-back process thereon.

A method of forming a FinFET according to another example embodiment of the present invention will now be described with reference to FIGS. 8 through 10. The example embodiment illustrated in FIGS. 8-10 may be similar to the example embodiment illustrated in FIGS. 5-7, except for the formation of the source/drain region 30S/D. Referring to FIG. 8, after the source/drain fins are recessed as illustrated in FIGS. 5 through 6, an etch stopper layer 60 and an interlayer insulating layer 70 may be formed. The etch stopper layer 60 and the interlayer insulating layer 70 may be formed of materials having an etch selectivity with respect to each other. For example, the etch stopper layer 60 may be a silicon nitride layer having a thickness in a range of about 50 to 200 Å. For example, the interlayer insulating layer 70 may be an undoped oxide layer of undoped silicated glass (USG), high temperature oxide (HTO), medium temperature oxide (MTO), tetra ethyl ortho silicate (TEOS), high density plasma (HDP), a doped oxide layer of boro phospho silicate glass (BPSG), phospho silicate glass (PSG), phospho silicate glass (PSG), and boro silicate glass (BSG). At least two of the aforementioned layers may be used to form the interlayer insulating layer 70.

The etch stopper layer 60 may be formed on, for example, a top surface of the gate electrode 40, side surfaces of the gate spacers 50, the vertical connection portions 35 of the fin 30, and the source/drain fins. The interlayer insulating layer 70 may be formed on the etch stopper layer 60.

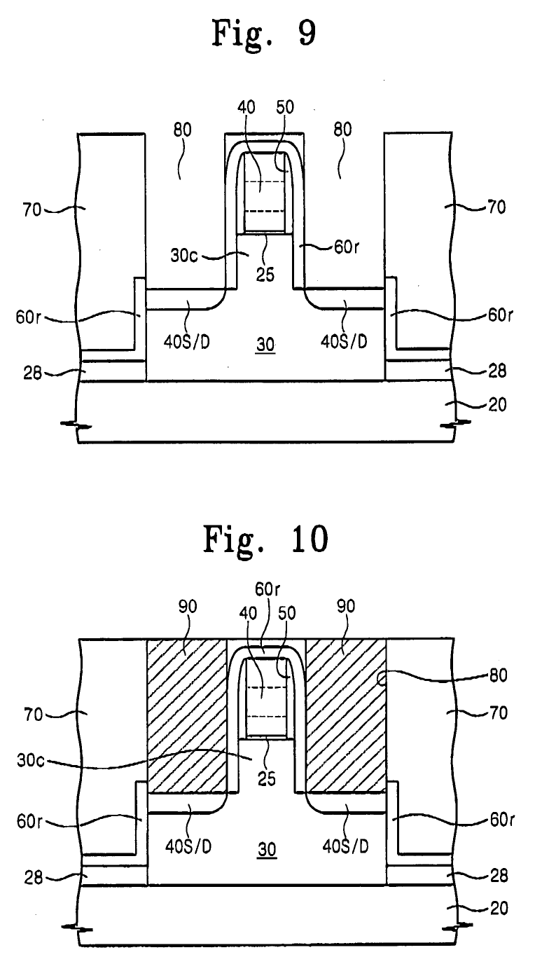

Referring to FIG. 9, the interlayer insulating layer 70 may be etched by using a self-aligned etching process until the etch stopper layer 60 is exposed. The etching process may also form holes 80 in which self-aligned contact pads 90 may be formed. The contact holes 80 may expose the source/drain fins. The etching process may leave an etch stopper layer pattern 60r on both sidewalls and a top surface of the gate electrode 40. An ion implantation process may be performed by using the etch stopper layer pattern 60r as an etch mask to form source/drain regions 40S/D on the source/drain fin regions at both sides of the gate electrode 40. The etch stopper layer pattern 60r on the vertical connection portions 35 may prevent impurity ions from being implanted into the vertical connection portions 35 during the ion implantation process.

Referring to FIG. 10, a conductive layer of, for example, polysilicon may be formed to fill the contact holes 80 to form contact pads 90 to electrically connect to the source/drain regions 40S/D. For example, polysilicon may be deposited on the interlayer insulating layer 70 to completely fill the contact holes 80, and then a planarization process, for example, a chemical mechanical polishing (CMP) process or an etch-back process may be performed until the remaining etch stopper layer pattern 60r on the gate electrode 40 is exposed, thereby forming the contact pads 90 in the respective contact holes 80.

In the example embodiment described with reference to FIGS. 8 through 10, if the contact hole 80 also exposes the top surface of the gate electrode 40, the etch stopper layer pattern 60r on the top surface of the gate electrode 40 may be removed. In this case, the remaining etch stopper layer pattern 60r may correspond to the protective spacers 55 of FIGS. 5 through 7.

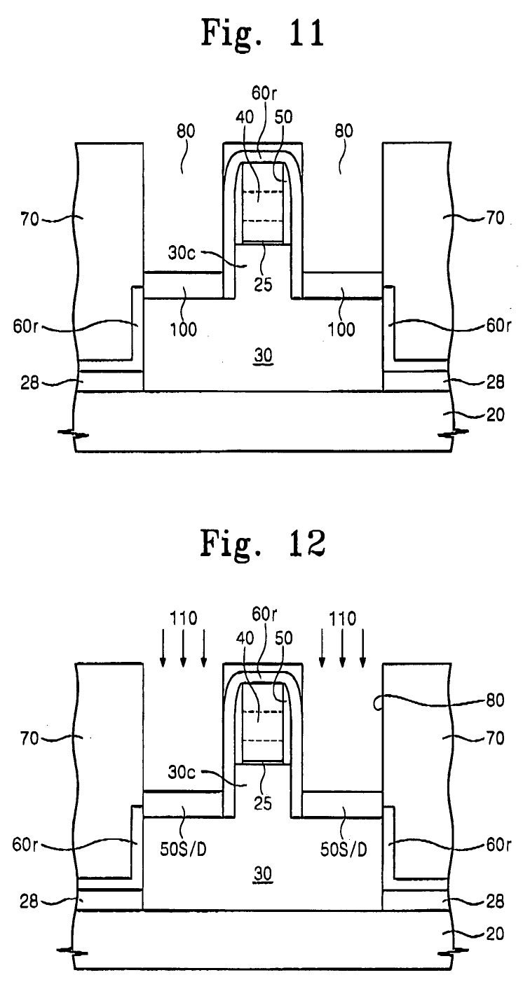

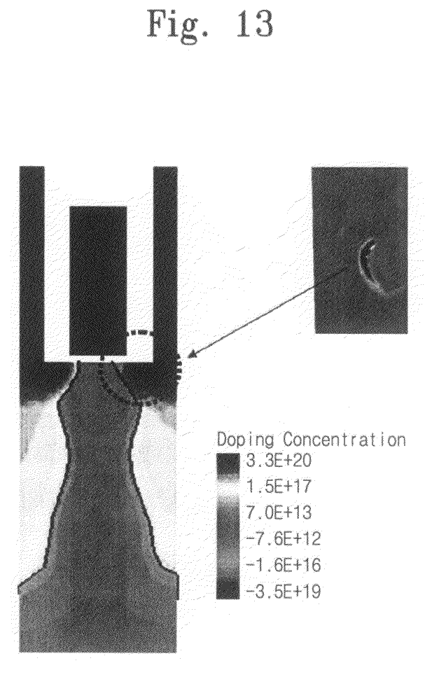

A method of forming a FinFET according to another embodiment of the present invention will now be described with reference to FIGS. 11 and 12. In the example embodiment, an epitaxial growth method may be used to form source/drain regions 50S/D. Referring to FIG. 11, after the source/drain fins are recessed, an epitaxial process may be used to form epitaxial layers 100 as the source/drain regions 50S/D on both sides of the gate electrode 40. A height of the source/drain regions may be suitably controlled for specific device characteristics by controlling the epitaxy process. For example, the epitaxial layers 100 may be higher than a top surface of a gate fin 30C. In this case, the gate spacers 50 and the remaining etch stopper layer pattern 60r may be interposed between the epitaxial layers 100 and the gate electrode 40.

Referring to FIG. 12, an ion implantation process 110 may be performed to form source/drain regions 50S/D in the epitaxial layers 100. The top surface of the source/drain regions 50S/D may be higher than the top surface of the fin 30 acting as a channel region under the gate electrode 40.

A simulation was conducted in order to examine characteristics of a FinFET having recess source/drain regions according to example embodiments of the present invention. In the simulation, recesses for the source/drain regions were set to about 400 Å in a virtual FinFET corresponding to the FinFET according to the example embodiments of the present invention. Phosphorus impurities for a virtual ion implantation process for the source/drain regions were set to about 1×10¹³ atoms/cm². For comparison, a simulation was conducted on a conventional FinFET having un-recessed source/drain regions.

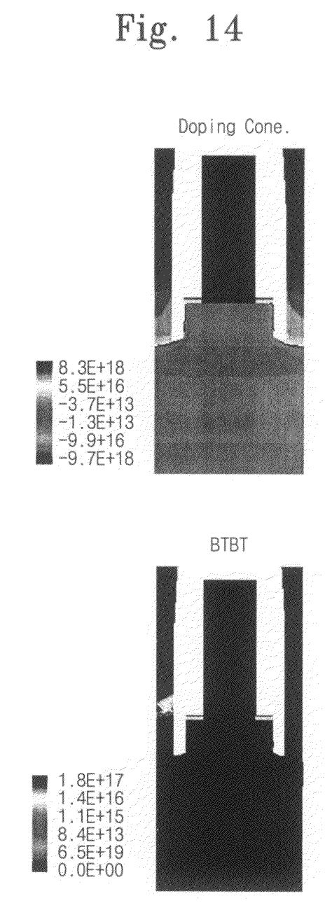

FIG. 13 illustrates a result of the simulation of the conventional FinFET. FIG. 14 illustrates a result of the simulation of the FinFET according to an example embodiment of the present invention.

Referring to FIG. 13, the simulation result of the general FinFET demonstrates that GIDL may be caused because band to band tunneling (BTBT) occurs in a highly-doped region where source/drain regions and a gate electrode on a fin overlap each other. In FIG. 13, a region where the doping concentration and BTBT generation rate are the highest are shown in red, and a region where they are the lowest is shown in blue.

In contrast, referring to FIG. 14, the simulation result of the FinFET according to the example embodiments of the present invention reveals that GIDL may be prevented because almost little to no doping concentration is observed in a region where source/drain regions and a gate electrode on a top surface of a gate fin overlap each other, therefore, BTBT is not observed. In FIG. 14, a region where the doping concentration and BTBT generation rate are the highest are shown in red, and a region where they are the lowest is shown in blue.

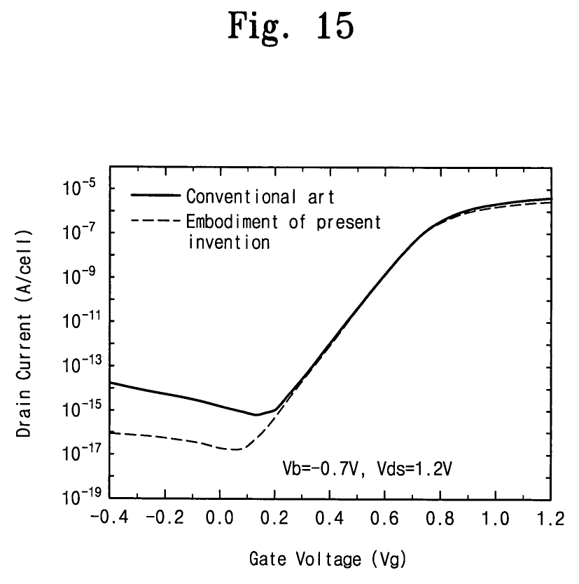

FIG. 15 illustrates Id-Vg curves of the conventional art and the example embodiments of the present invention depending on the simulation results of FIGS. 13 and 14, respectively. Referring to FIG. 15, the FinFET according to example embodiments of the present invention may reduce the GIDL more than an order of 2 under a condition of Vg<0 V.

FinFET characteristics based on the simulation results are shown in Table 1 below.

TABLE 1

| | Ion | Threshold | | | GIDL of |
|---|---|---|---|---|---|
| | implantation | voltage | DIBL | On current | gate voltage |
| | energy (keV) | (V) | (mV) | (μA/cell) | below 0 V |
| Conventional | 30 | 0.654 | 21 | 8.8 | 2.00 × 10⁻¹⁵ |
| FinFET | | | | | |
| FinFET of | 15 | 0.681 | 13 | 2.9 | 2.10 × 10⁻¹⁷ |
| example | 10 | 0.667 | 14 | 3.2 | 1.70 × 10⁻¹⁷ |
| embodiments | 5 | 0.711 | 16 | 3.2 | 2.00 × 10⁻¹⁷ |

From Table 1, as it can be seen the example embodiments of the present invention may contribute to lowering the GIDL, compared to the conventional FinFET. Furthermore, according to example embodiments of the present invention, the On current characteristic may be improved and the DIBL may be reduced, compared to the conventional FinFET. Also, as it can be seen, according to example embodiments of the present invention, characteristics such as the threshold voltage, DIBL, On current and GIDL may not be changed even if the magnitude of the ion implantation energy is changed.

According to example embodiments of the present invention, in recess source/drain regions, an overlap between a gate and source/drain regions may be distanced from a gate electrode on a top surface of a gate fin by a recess depth. Thus, influence of the upper gate electrode may be decreased, and thus GIDL deterioration may be reduced.

What is claimed is:

1. A semiconductor device, comprising:
a fin provided on a substrate and extending in a first direction, the fin including a stepped portion; and
a gate electrode extending in a second direction crossing the first direction, and provided on a top surface and side surfaces of the stepped portion of the fin.

2. The semiconductor device of claim 1, further comprising:
source/drain regions provided in the fin on either side of the stepped portion.

3. The semiconductor device of claim 2 further comprising:
an interlayer insulating layer including contact holes and provided between the fin and gate electrode; and
contact pads provided in the contact holes.

4. The semiconductor device of claim 2, further comprising:
gate spacers provided on sidewalls of the gate electrode in the first direction.

5. The semiconductor device of claim 4, further comprising:
an etch stopper layer pattern provided on sidewalls of the stepped portion of the gate in the second direction.

6. The semiconductor device of claim 5, wherein the gate spacer and the etch stopper layer pattern are formed of a same material.

7. The semiconductor device of claim 5, wherein the etch stopper layer pattern is further provided on sidewalls of the gate spacers and a top surface of the gate electrode.

8. The semiconductor device of claim 1, wherein a height of the stepped portion extending from the fin ranges from about 150 to 500 Å.

9. The semiconductor device of claim 1, further comprising:
epitaxial layers provided on portions of the fin on either side of the stepped portion, wherein source/drain regions are provided on the epitaxial layers.

10. The semiconductor device of claim 1, further comprising:
a gate insulating layer provided between the gate electrode and the stepped portion of the fin.

11. A method of forming a semiconductor device, the method comprising:
forming a fin to extend in a first direction on a substrate;
forming a gate electrode structure to extend in a second direction crossing the first direction on a top surface and sidewalls of the fin;
recessing the exposed portions of the fin at both sides of the gate electrode structure to a desired depth to form a stepped portion under the gate electrode structure; and
implanting impurity ions into the recessed portion of the fin to form source/drain regions.

12. The method of claim 11, wherein the recessing the exposed portions comprises:
forming gate spacers on both sidewalls of the gate electrode structure; and
recessing the exposed portion of the fin by using the gate spacers and the gate electrode structure as an etching mask.

13. The method of claim 12, wherein the forming of the source/drain regions comprises:
forming an etch stopper layer on the substrate;
forming an interlayer insulating layer on the etch stopper layer;
etching the interlayer insulating layer to expose the etch stopper layer;
removing the etch stopper layer over the recessed portions to form contact holes; and
implanting the impurity ions into the recessed portions through the contact holes.

14. The method of claim 13, wherein the gate spacers and the etch stopper layer are formed of a material having an etch selectivity with respect to the interlayer insulating layer.

15. The method of claim 11, further comprising:
forming a protective layer on the substrate after the recessing of the exposed portions; and
performing an etch-back process on the protective layer.

16. The method of claim 11, further comprising:
growing epitaxial layers on the recessed portions; and
implanting the impurity ions into the epitaxial layers to form the source/drain regions.

17. The method of claim 11, further comprising:
performing a thermal oxidation process after recessing the exposed portions.

18. The method of claim 11, wherein the forming of the gate electrode structure comprises:
forming a gate insulating layer on a surface of the step portion of the fin; and
forming a gate electrode on the gate insulating layer.

19. The method of claim 11, wherein the recessing of the exposed portions recesses the exposed portions such that a height difference between the fin including the stepped portion and fin not including the stepped portion ranges from about 150 to 500 Å.
